(19) United States
(12) Patent Application Publication
(10) Pub. No.: US 2010/0147677 A1
(43) Pub. Date: Jun. 17, 2010

(54) DRUM DESIGN FOR WEB PROCESSING

(76) Inventors: Mustafa Pinarbasi, Morgan Hill, CA (US); Homayoun Talieh, Saratoga, CA (US); Bulent M. Basol, Manhattan Beach, CA (US)

Correspondence Address: PILLSBURY WINTHROP SHAW PITTMAN LLP, P.O. BOX 10500, MCLEAN, VA, 22102, US

(21) Appl. No.: 12/607,689

(22) Filed: Oct. 28, 2009

Related U.S. Application Data
(60) Provisional application No. 61/109,144, filed on Oct. 28, 2008.

(51) Int. Cl. C23C 14/34; C23C 14/56

(52) U.S. Cl. 204/192.1; 204/298.24; 118/500

(57) ABSTRACT

A roll to roll system for depositing a material on a workpiece is provided. In one embodiment, the system includes a drum, which rotates about an axis that is transverse to a process direction, and a number of PVD deposition units. The drum further includes a peripheral surface that includes a groove having a recessed workpiece contact surface that is parallel to the axis and disposed between a first side wall and a second side wall. A portion of the recessed workpiece contact surface supports a section of the workpiece and the first and second side walls maintain the section of the workpiece on the portion of the recessed workpiece contact surface as the workpiece is moved along the process direction. The PVD deposition units are disposed across from some of the portion of the peripheral surface and continuously deposit the material across a width of some of the section of the workpiece.

### CROSS REFERENCE TO RELATED APPLICATIONS

This application claims priority to U.S. Application No. 61/109,144 filed Oct. 28, 2008 entitled “IMPROVED DRUM DESIGN FOR WEB PROCESSING”, the entire contents of which are incorporated herein by reference.

### BACKGROUND

1. Field of the Invention

This invention relates to deposition methods and, more particularly, to methods for physical vapor deposition of metallic thin films on a conductive surface for manufacturing solar cells.

2. Description of the Related Art

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ, where 0≦x≦1, 0≦y≦1 and k is approximately 2, have already been employed in solar cell structures that yielded conversion efficiencies approaching 20%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications.

The structure of a conventional Group IBIIIAVIA compound photovoltaic cell such as a Cu(In,Ga,Al)(S,Se,Te)₂ thin film solar cell is shown in FIG. 1. The device 10 is fabricated on a substrate 11, such as a sheet of glass, a sheet of metal, an insulating foil or web, or a conductive foil or web. The absorber film 12, which includes a material in the family of Cu(In,Ga,Al)(S,Se,Te)₂, is grown over a conductive layer 13 or contact layer, which is previously deposited on the substrate 11 and which acts as the electrical contact to the device. The absorber film 12 is formed by depositing a precursor layer including Group IB and Group IIIA elements on the contact layer and then reacting this precursor stack film with one of Se and S to form the absorber layer. The substrate 11 and the conductive layer 13 form a base 20 on which the absorber film 12 is formed. Various conductive layers comprising Mo, Ta, W, Ti, and their nitrides have been used in the solar cell structure of FIG. 1. If the substrate itself is a properly selected conductive material, it is possible not to use a contact layer 13, since the substrate 11 may then be used as the ohmic contact to the device. After the absorber film 12 is grown, a transparent layer 14 such as a CdS, ZnO or CdS/ZnO stack is formed on the absorber film. Radiation 15 enters the device through the transparent layer 14. Metallic grids (not shown) may also be deposited over the transparent layer 14 to reduce the effective series resistance of the device.

A variety of materials, deposited by a variety of methods such as evaporation, electroplating and sputter deposition, can be used to provide the various layers of the device shown in FIG. 1. Sputtering and evaporation techniques, which are also known as physical vapor deposition (PVD) techniques, are the preferred methods to deposit contact layers and transparent layers, although they may be used to deposit the components of the precursor films also. Such layers can be deposited on a continuous flexible substrate using a well known roll to roll process tool in which the flexible substrate is fed from a supply roll into a process chamber and after receiving deposition the flexible substrate is taken up from the process chamber and wrapped around a receiving roll. The process chamber can have for example one or more sputter deposition units or cathodes to deposit a desired material onto the continuous flexible substrate from the targets mounted on the cathodes.

In general, the process chambers are equipped with a support apparatus to support the continuous flexible substrate during the deposition. FIG. 2 shows in perspective view of an exemplary cylindrical support apparatus 50 or drum, supporting a continuous flexible workpiece 52 or web. Drums with various sizes are used to control the tension of the web and to transfer the heat out of the web. The drums can be using oil, water, or gas based cooling mechanisms to transfer heat from the web that gets heated by the sputtering cathodes. Top surface 54 of the web 52 is exposed to the depositing material (depicted as arrows “M”) originating from the target materials mounted on the cathodes. During the process, the web 52 is advanced while in contact with the curved surface 56 of the drum 50 which can rotate as the workpiece moves. The quality of the deposited film depends upon the physical contact between the web and the drum surface. As shown in FIG. 2, the curved surface 56 is a perfectly cylindrical surface.

During the process, small distortions in the web may disturb the physical contact between the web and the curved surface which may cause the web to move non-uniformly such as side ways, and/or up and down on the curved surface. Distortions in the web can be caused by the process temperature. Such distortions in turn affect the quality of the deposited layer and cause contamination of an edge area 58 of the curved surface 56, which further deteriorate the physical contact between the web and the curved surface as the web edge contacts this contaminated edge of the curved surface. As a result, an improved drum design is needed to address the above described issues so that more optimal process results may be obtained.

### SUMMARY OF THE INVENTION

The present invention provides a method an apparatus for the confinement of the web in a specific section of a drum, a better web contact with cooled surfaces, and depositing on the full width of the web on the drum.

In a first embodiment, the drum has a groove that guides the web. This allows the web to be confined to specific section of the drum that is kept free of deposits. With this approach, full width of the web can be deposited. Since the web is confined to groove, deposition on the drum takes place on the sides of the web. Since these areas are not traveled by the web, deposits can be removed with known methods without impacting the interaction between the web and the drum.

In a second embodiment, a buffer material in the form of a buffer belt or a buffer layer is placed between the drum and the web. The buffer material can be highly conductive yet flexible material. The width of the buffer material can be wide enough to capture all deposition flux. Once significant deposition is made either the buffer material can be cleaned or replaced with a new one.

### BRIEF DESCRIPTION OF THE DRAWINGS

FIG. 1 is a schematic view of a prior art solar cell structure;

FIG. 2 is a perspective view of a prior art;

FIG. 3A is a schematic view of a roll to roll deposition system of the present invention having a drum to support a continuous substrate, wherein the drum surface includes a groove to guide the continuous substrate;

FIG. 3B is schematic side view of an embodiment of the drum shown in FIG. 3A;

FIG. 4A is a schematic view of another embodiment of a roll to roll deposition system of the present invention having a drum to support a continuous substrate, wherein the drum includes a smooth surface, and wherein a buffer belt has been disposed between the drum surface and the continuous substrate;

FIG. 4B is schematic side view of the drum shown in FIG. 4A;

FIG. 4C is a schematic side view of the drum shown in FIG. 3B, wherein a buffer belt has been disposed between the drum surface and the continuous substrate;

FIG. 5A is schematic view of the roll to roll system shown in FIG. 4A, wherein the buffer belt has been replaced with a buffer layer that is coated on the drum surface;

FIG. 5B is schematic side view of the drum shown in FIG. 5A; and

FIG. 5C is a schematic side view of the drum shown in FIG. 3B, wherein a buffer layer has been disposed between the drum surface and the continuous substrate.

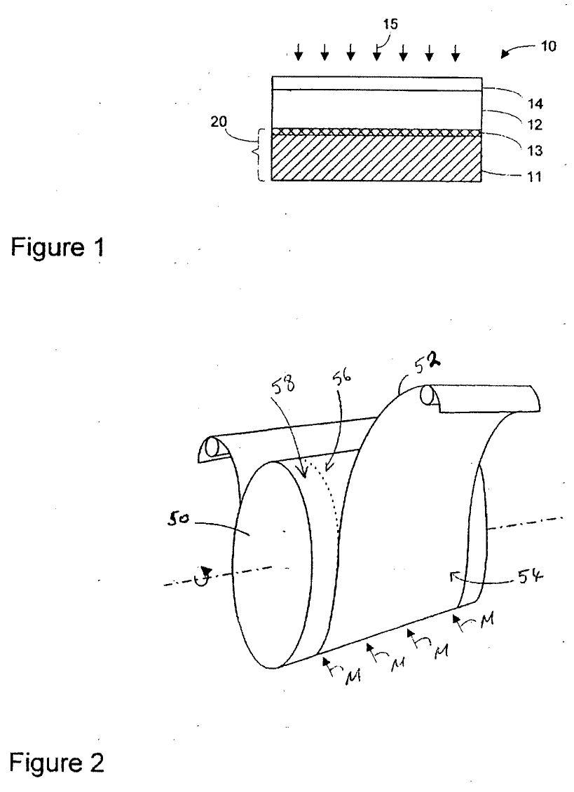

### DETAILED DESCRIPTION OF THE INVENTION

The present invention provides a system for depositing thin films on a continuous substrate or web which is supported by a curved surface of a support base of the system during the deposition. In one embodiment the support base may have a cylindrical shape having a curved surface with a groove region that a continuous substrate is supported during the deposition process. The groove region prevents the substrate from slipping sideways and controls the movement of the substrate. In another embodiment, a flexible buffer material is disposed between the substrate and the curved surface of the support base. The flexible buffer material increases the friction between the substrate and the surface of the drum by making a better contact with the substrate and reduces the distortions or quilting caused by the excessive heat. The flexible buffer material can accommodate the small distortion on the substrate and make contact with the full substrate surface. This significantly enhances the heat transfer from the distorted areas of the continuous substrate. A roll to roll system of the present invention may be used to manufacture Group IBIIIAVIA thin film solar cells.

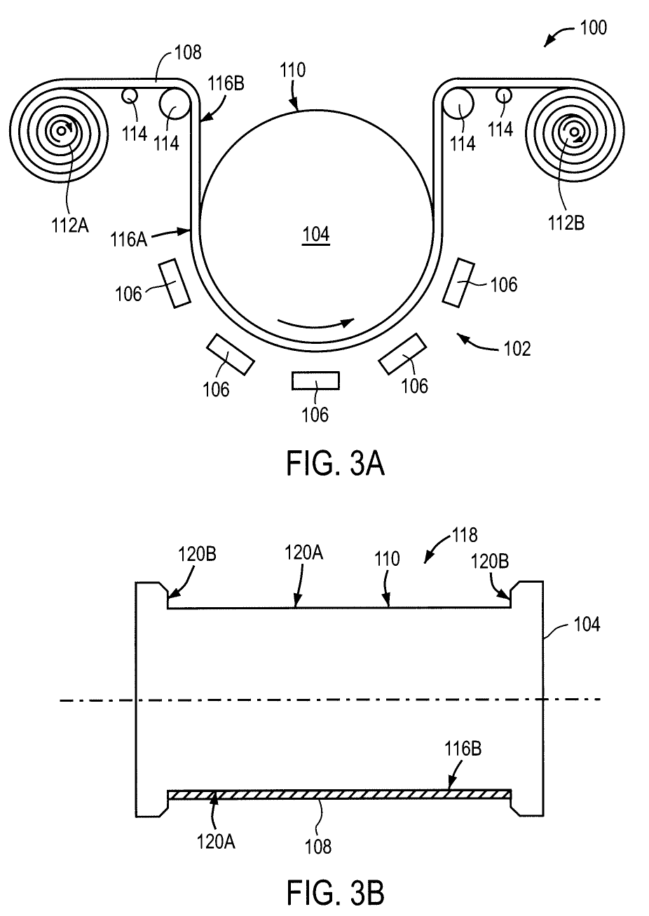

FIG. 3A shows a roll to roll system 100 with a deposition station 102. The deposition station 102 may be in a chamber or enclosure (not shown). The chamber may or may not be under vacuum. The deposition station includes a support base or drum 104 to support a workpiece 108 during a deposition process. One or more deposition units 106 for a PVD process, such as sputter deposition units, is generally positioned across from the lower half of the drum 104. The workpiece 108 contacts a cylindrical peripheral surface 110 of the drum as it is extended between a supply spool 112A and a receiving spool 112B. A number of auxiliary rollers 114 are symmetrically positioned at both sides of the drum to enable workpiece 108 to contact to at least a lower half of the cylindrical peripheral surface 110 as the workpiece is fed from the supply spool 112A and wrapped around the receiving spool 112B after the process. As the workpiece 108 is advanced along a process direction ‘A’ by a moving mechanism (not shown), it is tensioned on the surface 110 of the drum 104 and a front surface 116A of the workpiece 108 receives depositing material from the deposition units 106 while a back surface 116B of the workpiece 108 is in physical contact with the surface 110 of the drum 104. Both long edges of the workpiece 108 are substantially parallel to the process direction ‘A’. The material from the deposition units 106 deposits onto a deposition path on the front surface 116A of the workpiece 108 as the workpiece is advanced in front of the units 106. The deposition units may include sputter deposition apparatus to sputter-deposit a material onto the front surface 116A of the workpiece. The deposition path may have a width which is equal to or less than the width of the workpiece.

The drum 104, in all of the embodiments, is made from a heat conducting material, preferably a metallic material such as stainless steel, though other heat conducting materials can be used. Conventional known methods can be used to make the drums. Modified process steps are required for making the grooves as described above, and additional process steps are used when adding additional materials such as the flexible buffer layer described below. It is noted that the dimension of a typical drum 102 can vary, though in many implementations a diameter of 3-10 ft is typical. A web width of around 2-6 ft is also typical in manufacturing environments.

FIG. 3B shows the side cross sectional view of the drum 104. In this embodiment the peripheral surface 110 of the drum 104 includes a groove 118 having a peripheral recessed surface 120A and side walls 120B (a first side wall and a second side wall). As the workpiece moved during the process, the back surface 116B of the workpiece 108 contacts the peripheral recessed surface 120A, also referred to as a workpiece contact surface, and the side walls 120B confine the workpiece 108 within the groove 118. The groove has an unvarying depth across the cylindrical surface 110, which is in the range of the workpiece thickness or greater. The groove 118 enables workpiece to stay in the deposition path and move in the process direction ‘A’. If any contamination happens, the contamination stays on the side walls 120B, and since the workpiece 108 cannot move laterally, no substantial contamination gets underneath the workpiece 108. Contaminated areas of the side walls 120B can be cleaned at process intervals. In this design workpiece 108 will be guided to the groove and the same area will always be kept clean ensuring near constant interaction between the workpiece 108 and the drum 104. Since the workpiece 108 is confined into the groove 118 and moves only in the process direction ‘A’, the material from the deposition units 106 may be deposited onto the full front surface of the workpiece in an edge to edge manner covering the full width without concerning about any unwanted deposition over the side walls 120B because the side walls are not contacted by the workpiece 108.

In the above embodiment, the groove region of the surface of the drum prevents the workpiece from slipping sideways and controls the movement of the workpiece. The movement of workpiece may also be controlled by a flexible buffer material such as a silicon based polymer material that is disposed between the workpiece and the surface of the drum. The flexible buffer material increases the friction between the workpiece and the drum surface by making a better contact with the back of the workpiece, thereby reducing the distortions or quilting caused by the excessive heat. The buffer material may be used with the drums having grooves as described above as well as with a regular drum with a smooth surface which does not include any groove.

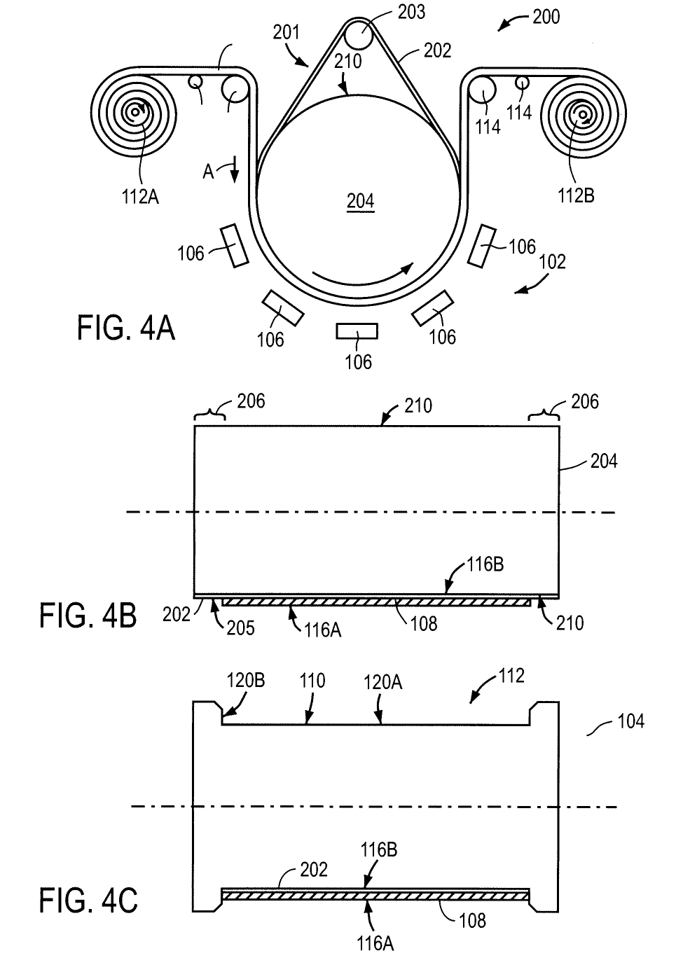

FIG. 4A shows a system 200 which is similar to the system 100 except the system 200 uses another drum embodiment and an associated buffer belt assembly. The system 200 is constructed with replacing the drum 104 of the system 100 in FIGS. 3A-3B with a drum 204 without a groove and also including a buffer belt assembly 201 to provide buffer material. As shown in FIG. 4B, in this embodiment a cylindrical surface 210 of the drum 204 is a smooth surface without a groove. A buffer belt 202 is positioned between the surface 210 of the drum and the back surface 116B of the workpiece 108. The buffer belt 202 is tensioned by a belt roller 203 which may move vertically. The width of the buffer belt 202 may preferably be equal to the width of the surface 210 of the drum 204. The width of the buffer belt may be equal to or greater than the width of the workpiece 108. If the width of the buffer belt 202 is greater than the width of the workpiece, sides 205 of the buffer belt 202 may be exposed, not covered by the workpiece 108. The exposed sides 205 collect the unwanted deposited material and keep edge surfaces 206 of the drum 204 free from contaminants or excess deposited material. Surfaces of the sides 205 of the buffer belt may be made rough while a surface section of the buffer belt 202 that goes under the workpiece 108 may have a smooth surface for better heat transfer. A smooth surface in the application may have a surface roughness (peak to valley) of 50-250 nm. A roughened surface that collects the excess deposited material or contaminants may have a surface roughness in the range of tens of micrometers up to a millimeter. Such rough surfaces are typically obtained by plasma spraying a material such as aluminum on the surface to be roughened. This way the rough surfaces of the exposed sides 205 may help to collect a greater amount of contaminants before they are cleaned and thereby reduce the number of process interruptions for cleaning.

The buffer belt 202 may comprise a material that is flexible yet thermally very efficient conductor such as silicones filled with high thermal conductivity materials. A flexible belt will make a better contact with the workpiece 108 and reduce the distortions or quilting caused by excessive heat. The buffer belt 202 may accommodate the small distortion on the workpiece 108 and make contact with full back surface 116B of the workpiece. This buffer belt 202 will significantly enhance the heat transfer from distorted areas of the workpiece 108 compared to solid surfaces in the prior art. Furthermore, the buffer belt 202 can be driven by a motorized roll or be driven by the drum; the tension on the belt can be controlled by the belt roller 203, for example the buffer belt 202 can have a constant tension setting with spring such that it can move close or away from the drum 210 freely to keep the constant tension; the buffer belt 210 can have an edge guide to control its precise position on the drum; and the belt can be cleaned or replaced once exposed sides receive significant deposits. In another embodiment, the buffer belt 202 may be replaced with a pair of cleaning belts (not shown) which may only touch and cover the edge surfaces 206 of the drum 204 but not extend under the workpiece 108 so that the back surface 116B of the workpiece touch and cover the surface area between the edge surfaces 206. The surface of the cleaning belts may be rough to collect the contaminants. Cleaning belts may be cleaned at intervals or replaced with the clean ones.

As shown in FIG. 4C, the system 200 may also use the drum 104, which is described in the previous embodiment, in combination with the buffer belt 202 described above. In this embodiment, the buffer belt 202 is between the recessed surface 120A and the back surface 116B of the workpiece 108. The side walls 120B confines the workpiece 108 and the buffer belt 200 within the groove 118.

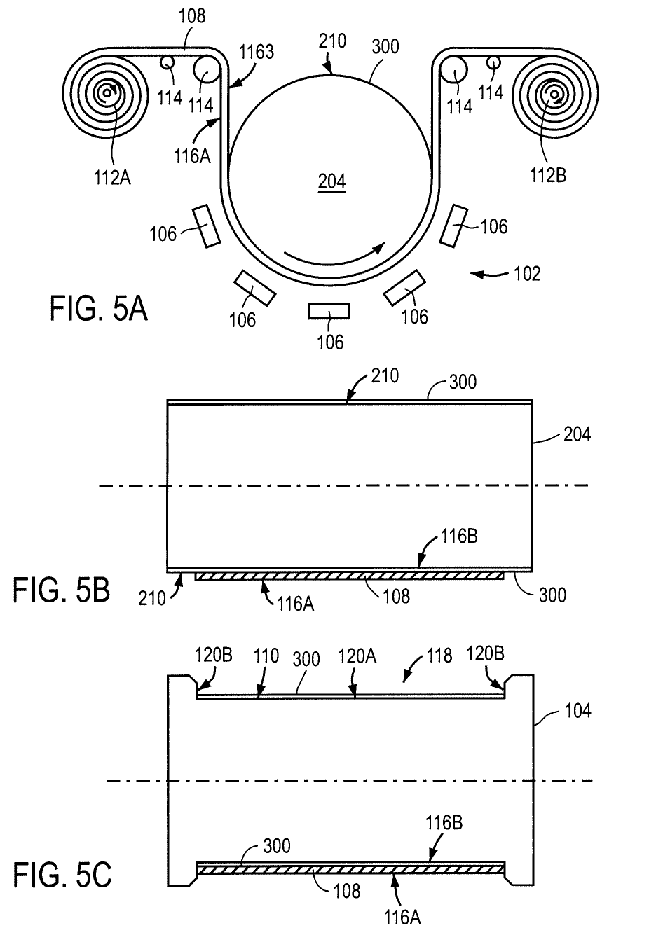

As shown in FIGS. 5A-5B, the buffer belt 202 shown in FIG. 4A may be replaced with a buffer material layer 300 that is coated on the entire cylindrical surface 210 that touches the workpiece 108 for the same effect. The width of the buffer layer 300 may preferably be equal to the width of the surface 210 of the drum 204. The width of the buffer layer 300 may be equal to or greater than the width of the workpiece 108. If the width of the buffer layer 300 is greater than the width of the workpiece, sides of the buffer layer 300 may be exposed, not covered by the workpiece 108.

As shown in FIG. 5C, the buffer layer may also be employed on the surface 110 of the drum 104 shown in FIG. 3B. In this embodiment, the buffer layer 300 is between the recessed surface 120A and the back surface 116B of the workpiece 108. The side walls 120B and the buffer layer 300 confine the workpiece 108 within the groove 118. In this embodiment, the buffer layer 300 functions the same way as the buffer belt 202 shown in FIG. 4C.

Although the present invention is described with respect to certain preferred embodiments, modifications thereto will be apparent to those skilled in the art.

We claim:

1. A system for depositing a material on a continuous flexible workpiece advanced in a process direction, comprising:
at least one drum that rotates about an axis that is transverse to the process direction, the at least one drum further including a peripheral surface that includes a groove formed therein, thereby resulting in a recessed workpiece contact surface that is parallel to the axis and which is disposed between a first side wall and a second side wall, wherein a portion of the recessed workpiece contact surface supports a section of the continuous flexible workpiece and the first and second side walls maintain the section of the continuous flexible workpiece on the portion of the recessed workpiece contact surface as the continuous flexible workpiece is moved along the process direction; and
at least one deposition unit disposed across from some of the portion of the peripheral surface, the at least one deposition unit continuously depositing the material across a width of some of the section of the continuous flexible workpiece.

2. The system of claim 1 further comprising a supply roll from which the continuous flexible workpiece is advanced in the process direction towards the at least one drum, and a receiving roll that the continuous flexible workpiece received from the at least one drum is wrapped around.

3. The system of claim 1, wherein the at least one drum has a cylindrical shape and the recessed workpiece contact surface has a cylindrical shape.

4. The system of claim 1, wherein the at least one deposition unit comprises a sputter deposition apparatus.

5. The system of claim 3, wherein the drum is cooled by a fluid, thereby providing for transfer of heat from the continuous flexible workpiece to the at least one drum while the at least one deposition unit continuously deposits the material across the width of some of the section of the continuous flexible workpiece.

6. The system of claim 2 further comprising a chamber to enclose the at least one drum and the at least one deposition unit.

7. The system of claim 6, wherein the chamber is a vacuum chamber.

8. The system of claim 1, further including a plurality of rollers positioned along the process direction to stabilize the continuous flexible workpiece prior to and after the continuous flexible workpiece supports the recessed workpiece contact surface of the at least one drum.

9. The system of claim 1, wherein the at least one drum includes one or more drums disposed along the process direction.

10. A system for depositing a material on a continuous flexible workpiece advanced in a process direction, comprising:
at least one drum that rotates about an axis that is transverse to the process direction, the at least one drum further including a peripheral surface that is parallel to the axis and which extends from a first edge to a second edge;
a buffer film that is flexible and highly thermally conductive that covers at least a portion of the peripheral surface to support a section of the continuous flexible workpiece, wherein the portion of the peripheral surface covered by the buffer film extends from the first edge to the second edge of the peripheral surface; and
at least one deposition unit disposed across from the portion of the peripheral surface, the at least one deposition unit continuously depositing the material across a width of some of the section of the continuous flexible workpiece.

11. The system of claim 10 further comprising a supply roll from which the continuous flexible workpiece is advanced in the process direction towards the support device, and a receiving roll that the continuous flexible workpiece received from the at least one drum is wrapped around.

12. The system of claim 10, wherein the at least one drum has a cylindrical shape and the peripheral surface has a cylindrical shape.

13. The system of claim 10, wherein the at least one deposition unit comprises a sputter deposition apparatus.

14. The system of claim 12, wherein the at least one drum is cooled by a fluid, thereby providing for transfer of heat from the continuous flexible workpiece to the drum while the at least one deposition unit continuously deposits the material across the width of some of the section of the continuous flexible workpiece.

15. The system of claim 11 further comprising a chamber to enclose the at least one drum and the at least one deposition unit.

16. The system of claim 15, wherein the chamber is a vacuum chamber.

17. The system of claim 10, wherein the buffer film is a belt shaped buffer film tensioned by a tension roller to push the buffer film against the peripheral surface of the at least one drum.

18. The system of claim 17 wherein the belt shaped buffer film is made from silicone filled with a high thermal conductivity material.

19. The system of claim 10, wherein the buffer film is a buffer coating applied onto entire peripheral surface of the at least one drum.

20. The system of claim 19 wherein the buffer coating is made from silicone filled with a high thermal conductivity material.

21. The system of claim 19, wherein the buffer coating is a high friction material.

22. A method of depositing a material on a continuous flexible workpiece advanced in a process direction through a deposition chamber, comprising:
advancing the continuous flexible workpiece along a process direction and into the deposition chamber, wherein disposed in the deposition chamber is:
at least one drum that rotates about an axis that is transverse to the process direction, the at least one drum further including a peripheral surface that includes a groove formed therein, thereby resulting in a recessed workpiece contact surface that is parallel to the axis and which is disposed between a first side wall and a second side wall; and
at least one deposition unit disposed across from some of the portion of the peripheral surface,
supporting a back surface of the section of the continuous workpiece with a portion of the recessed workpiece contact surface, while the first and second side walls maintain the section of the continuous flexible workpiece on the portion of the recessed workpiece contact surface as the continuous flexible workpiece is moved along the process direction;
depositing the material onto an exposed surface of the section of the continuous flexible workpiece from the at least one deposition unit as the back surface of the section of the continuous flexible workpiece is supported by the portion of the recessed workpiece contact surface.

23. The method of claim 22, wherein the depositing deposits the material across an entire width of the exposed surface of the section of the continuous flexible workpiece and no material deposition occurs on the recessed workpiece contact surface.

24. The method of claim 23, wherein when the depositing deposits the material, deposition of excess material occurs on the first and second side walls.

25. The method of claim 24 further comprising the step of cleaning the excess material from the first and second side walls at process intervals.

26. The method of claim 22, wherein the step of depositing comprises sputter deposition.

27. A method of depositing a material on a continuous flexible workpiece advanced in a process direction through a deposition chamber, comprising:
advancing the continuous flexible workpiece along a process direction and into the deposition chamber, wherein disposed in the deposition chamber is:
at least one drum that rotates about an axis that is transverse to the process direction, the at least one drum further including a peripheral surface that is parallel to the axis and which extends from a first edge to a second edge;
a buffer film that is flexible and highly thermally conductive that covers at least a portion of the peripheral surface to support a section of the continuous flexible workpiece, wherein the portion of the peripheral surface covered by the buffer film extends from the first edge to the second edge of the peripheral surface; and
at least one deposition unit disposed across from the portion of the peripheral surface,
supporting a back surface of the section of the continuous workpiece with a portion of the buffer film and the portion of the peripheral surface therebelow as the continuous flexible workpiece is moved along the process direction;
depositing the material onto an exposed surface of some of the section of the continuous flexible workpiece from the at least one deposition unit as the back surface of the section of the continuous flexible workpiece is supported by portion of the buffer film and the portion of the peripheral surface therebelow as the continuous flexible workpiece is moved along the process direction.

28. The method of claim 27, wherein the depositing deposits the material across an entire width of the exposed surface of the section of the continuous flexible workpiece.

29. The method of claim 28, wherein when the depositing deposits the material, deposition of excess material occurs on buffer film edge regions.

30. The method of claim 27, wherein the step of depositing comprises sputter deposition.

31. The method of claim 27, wherein the buffer film is a belt shaped buffer film tensioned against the peripheral surface of the at least one drum.

32. The method of claim 27, wherein the buffer film is a buffer coating applied onto the peripheral surface of the at least one drum.
